(19) United States
(12) Patent Application Publication
(10) Pub. No.: US 2021/0056902 A1
(43) Pub. Date: Feb. 25, 2021

(54) DISPLAY DEVICE AND DRIVING METHOD

(71) Applicant: SHARP KABUSHIKI KAISHA, Sakai City, Osaka (JP)

(72) Inventor: KOHHEI TANAKA, Sakai City, Osaka (JP)

(21) Appl. No.: 17/042,891

(22) PCT Filed: Mar. 29, 2018
(86) PCT No.: PCT/JP2018/013173

§ 371 Date: Sep. 28, 2020

(51) Int. Cl. G09G 3/3233; G09G 3/3291; G09G 3/20; H01L 27/32

(52) U.S. Cl. CPC G09G 3/3233; H01L 27/3276; G09G 3/2092; G09G 3/3291

(57) ABSTRACT

In a display device, a pixel circuit includes a light-emitting element disposed between the first power source wiring line and the second power source wiring line, first and second conductive terminals of a first drive transistor and first and second conductive terminals of a switching control transistor which are disposed between the first power source wiring line and the second power source wiring line, and connected in series with the light-emitting element, and first and second conductive terminals of a second drive transistor which are disposed between the first power source wiring line and the second power source wiring line, connected in series with the light-emitting element, and connected in parallel with the first and second conductive terminals of the first drive transistor and the first and second conductive terminals of the switching control transistor.

### TECHNICAL FIELD

The present invention relates to a display device and a driving method capable of adjusting overall luminance.

### BACKGROUND ART

Conventionally, in displays for vehicles and the like, high luminance (hundreds of cd/m²) is required to facilitate viewing even in sunlight during the daytime, while display at a very small luminance (number cd/m²) is required when driving in the night. That is, in a display for vehicle or the like, it is necessary to achieve both high luminance display and low luminance display.

In displays using Organic Light Emitting Diode (OLED) elements as light-emitting elements, in general, the overall luminance has been conventionally adjusted using an emission driver that controls light emission. For example, luminance adjustment is performed by adjusting a time for an on state of a light emission control transistor in a pixel circuit in one vertical interval to adjust a time for a current flowing from a power source wiring line through the OLED element.

In addition, for example, PTL 1 and PTL 2 describe a related art of a pixel circuit.

### CITATION LIST

### Patent Literature

PTL 1: Japanese Patent Application Publication No. 2004-341368 A

PTL 2: International Application Publication No. WO 2009/098802

### SUMMARY OF INVENTION

### Technical Problem

However, a minimum light emission period that can be adjusted using the emission driver is one horizontal interval, and further lower luminance display cannot be performed. Therefore, in order to perform the further low luminance display, display must be performed with only a low gray scale video signal, but in this case, the number of gray scales that can be used is reduced, so gray scale expressiveness is impaired.

The present invention has been made in consideration of the above problem, and has an object to provide a display device and a driving method capable of realizing display at a luminance lower than low luminance display that is obtained by adjusting a light emission time without impairing the gray scale expressiveness.

### Solution to Problem

A display device according to an aspect of the present invention includes pixel circuits arranged in a matrix shape, a first power source wiring line provided with a first power supply voltage, a second power source wiring line provided with a second power supply voltage, and data signal lines each provided for each of columns and provided with a data voltage, wherein the pixel circuit includes a light-emitting element disposed between the first power source wiring line and the second power source wiring line and driven by a current, first and second conductive terminals of a first drive transistor and first and second conductive terminals of a switching control transistor which are disposed between the first power source wiring line and the second power source wiring line, and connected in series with the light-emitting element, and first and second conductive terminals of a second drive transistor which are disposed between the first power source wiring line and the second power source wiring line, connected in series with the light-emitting element, and connected in parallel with the first and second conductive terminals of the first drive transistor and the first and second conductive terminals of the switching control transistor which are connected in series, and a control terminal of the first drive transistor is electrically connected to a control terminal of the second drive transistor to be applied with a common signal.

### Advantageous Effects of Invention

According to an aspect of the present invention, display at a luminance lower than low luminance display that is obtained by adjusting a light emission time can be realized without impairing the gray scale expressiveness.

### BRIEF DESCRIPTION OF DRAWINGS

FIG. 1 is a circuit diagram illustrating a configuration example of a subpixel in a display region in a display device according to Embodiment 1.

FIG. 2 is a circuit diagram illustrating a configuration example of a subpixel in a display region in a display device according to Embodiment 2.

FIG. 3 is a circuit diagram illustrating a configuration example of a subpixel in a display region in a display device according to Embodiment 3.

FIG. 4 is a circuit diagram illustrating a configuration example of a subpixel in a display region in a display device according to Embodiment 4.

FIG. 5 is a circuit diagram illustrating a configuration example of a subpixel in a display region in a display device according to Embodiment 5.

FIG. 6 is a circuit diagram illustrating a configuration example of a subpixel in a display region in a display device according to Embodiment 6.

FIG. 7 is a circuit diagram illustrating a configuration example of a subpixel in a display region in a display device according to Embodiment 7.

FIG. 8 is a circuit diagram illustrating a configuration example of a subpixel in a display region in a display device according to Embodiment 8.

FIG. 9 is a circuit diagram illustrating a configuration example of a subpixel in a display region in a display device according to Embodiment 9.

### DESCRIPTION OF EMBODIMENTS

In a display device, a pixel that is a unit of display is constituted by three subpixels of a red color, a green color, and a blue color. One subpixel has one light-emitting element and a pixel circuit for causing the light-emitting element to emit the light. The pixel circuits are arranged in a matrix shape. The light-emitting element is an electro-optical element whose luminance and transmittance are controlled by a current. The light-emitting element is not particularly limited, but an OLED element can be used as the light-emitting element, for example.

At least a data signal line, a first power source wiring line, a second power source wiring line, and a switching control signal line are disposed in the display region. A first power supply voltage is provided to the first power source wiring line, and a second power supply voltage is provided to the second power source wiring line. The data signal line is provided for each of columns and is provided with a data voltage.

The pixel circuit includes at least a light-emitting element disposed between the first power source wiring line and the second power source wiring line, first and second conductive terminals of a first drive transistor and first and second conductive terminals of a switching control transistor which are disposed between the first power source wiring line and the second power source wiring line, and connected in series with the light-emitting element, and first and second conductive terminals of a second drive transistor which are disposed between the first power source wiring line and the second power source wiring line, connected in series with the light-emitting element, and connected in parallel with the first and second conductive terminals of the first drive transistor and the first and second conductive terminals of the switching control transistor which are connected in series, where a control terminal of the first drive transistor is electrically connected to a control terminal of the second drive transistor in such a way that a common signal is applied thereto.

Such a configuration of the pixel circuit can realize display at a luminance lower than low luminance display that is obtained by adjusting a light emission time without impairing the gray scale expressiveness. Next, Embodiments 1 to 9 will be specifically described with reference to the drawings. Note that, in Embodiments 1 to 9, for convenience of description, members having the same function as the members described in preceding embodiments are denoted by the same reference symbols, and descriptions therefor are not repeated.

### Embodiment 1

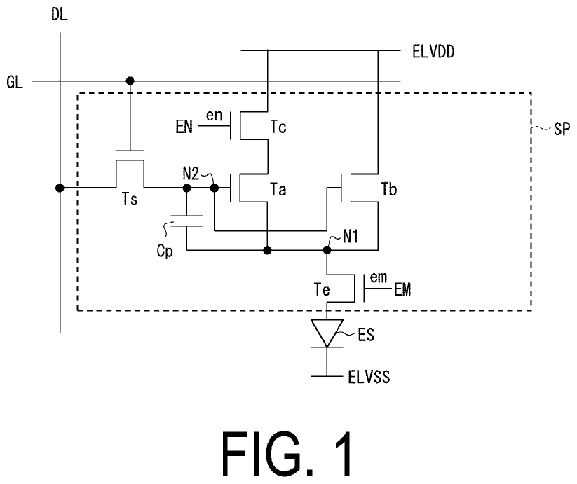

FIG. 1 is a circuit diagram illustrating a configuration example of a subpixel in a display region in a display device according to Embodiment 1. As illustrated in FIG. 1, a scanning signal line GL, a data signal line DL, a first power source wiring line ELVDD, a second power source wiring line ELVSS, a switching control signal line EN, and a light emission control signal line EM are disposed in the display region. The switching control signal line EN is a common wiring line connected to a pixel circuit SP of each subpixel in the display region, and a plurality of switching control signal lines EN are formed and a common signal is input to each of the switching control signal lines. A plurality of light emission control signal lines EM are formed, and different signals are input to the respective light emission control lines. The switching control signal line EN may be parallel or perpendicular to the light emission control signal line EM.

In the present embodiment, the pixel circuit SP includes two of the first drive transistor Ta and the second drive transistor Tb as drive transistors for driving the light-emitting elements ES, and includes the switching control transistor Tc that turns on and off supply of the current from the first drive transistor Ta. In addition, the pixel circuit SP conventionally includes a switch transistor (writing control transistor) Ts, a capacitance Cp, a light emission control transistor Te that controls a light emission timing of the light-emitting element ES.

The terminal of the second drive transistor Tb on a current input side (one of the first and second conductive terminals) is connected to the first power source wiring line ELVDD. Thus, a current is always supplied to the second drive transistor Tb from the first power source wiring line ELVDD.

On the other hand, the terminal of the first drive transistor Ta on a current input side (one of the first and second conductive terminals) is connected to a terminal of the switching control transistor Tc on a current output side (one of the first and second conductive terminals), and the terminal of the switching control transistor Tc on a current input side (the other of the first and second conductive terminals) is connected to the first power source wiring line ELVDD. In other words, the first drive transistor Ta on a current input side is connected via the switching control transistor Tc to a first pixel power source wiring line ELVDD. Therefore, the first drive transistor Ta is supplied with the current from the first power source wiring line ELVDD only when the switching control transistor Tc is in an on state.

The switching control signal line EN is connected to a control terminal of the switching control transistor Tc, to which a switching control signal en is input. The switching control transistor Tc is turned on and off based on the switching control signal en, and is in an off state when the switching control signal en is Low and in an on state when the switching control signal en is Hight.

The terminal of each of the first drive transistor Ta and the second drive transistor Tb like these on the current output side (the other of the first and second conductive terminals) is connected to a first node N1. The first node N1 is connected to a terminal of the light emission control transistor Te on a current input side, and a terminal of the light emission control transistor Te on a current output side is connected to a terminal of the light-emitting element ES on a current input side. In other words, the first node N1 is connected via the light emission control transistor Te to the light-emitting element ES.

A control terminal of the light emission control transistor Te is connected to the light emission control signal line EM, to which a light emission control signal em is input. The light emission control transistor Te is turned on and off based on the light emission control signal em, and is in an on state for a period while the light emission control signal em is Hight to supply the current to the light-emitting element ES from the first node N1. A terminal of the light-emitting element ES on a current output side is connected to the second power source wiring line ELVSS.

A control terminal of each of the first drive transistor Ta and the second drive transistor Tb is connected to a second node N2. The second node N2 is connected to a terminal of the switch transistor Ts on a current output side. The switch transistor Ts has a control terminal connected to a scanning signal line GN and a terminal on a current input side connected to the data signal line DL. The control terminals of the first drive transistor Ta and the second drive transistor Tb are connected via the switch transistor Ts to any one data signal line of the data signal lines DL each provided for each column.

The capacitance Cp is connected between the first node N1 and the second node N2. Specifically, a first conductive terminal of the capacitance Cp is connected to the control terminals of the control terminals of the first drive transistor Ta and the second drive transistor Tb. A second conductive terminal of the capacitance Cp is connected to either one of the conductive terminals of the first drive transistor Ta, and either one of the conductive terminals of the second drive transistor Tb. Also, as another configuration, the second conductive terminal of the capacitance Cp may be connected to either one of the conductive terminals of the first drive transistor Ta via the switching control transistor Tc.

In the pixel circuit SP having such a configuration, during the period while the light emission control transistor Te is in the on state, a current is supplied to the light-emitting element ES via the first node N1, and the light-emitting element ES emits light. The first node N1 is supplied with a current corresponding to a gray scale only from the second drive transistor Tb when the switching control signal en is Low, and is supplied with a current corresponding to a gray scale from both the second drive transistor Tb and the first drive transistor Ta when the switching control signal en is Hight.

Accordingly, the light-emitting element ES realizes low luminance light emission with the current supplied only from the second drive transistor Tb when the switching control signal en is Low, and realizes high luminance light emission with the current supplied from both the second drive transistor Tb and the first drive transistor Ta when the switching control signal en is Hight.

In this manner, the pixel circuit SP includes two of the first drive transistor Ta and the second drive transistor Tb as drive transistors to switch whether to be supplied with the current from the first drive transistor Ta by the switching control signal en. This allows switching between the low luminance display (low luminance mode) and the high luminance display (high luminance mode) by switching the switching control signal en, which is a technique absolutely different from the known technique for adjusting the time for supplying the current to the light-emitting element ES.

The luminance of the low luminance display depends on a current supply capability of the second drive transistor Tb. Therefore, the current supply capability of the second drive transistor Tb may be the same as a current supply capability of the first drive transistor Ta, but the current supply capability of the second drive transistor Tb is preferably smaller than the current supply capability of the first drive transistor Ta. This can increase a difference in luminance between the high luminance display and the low luminance display realized by switching the switching control signal en. For example, setting the current supply capability of the second drive transistor Tb to ½ that of the first drive transistor Ta (the current flowing in a case that a gate voltage is the same is half) allows the luminance of the low luminance display to be approximately ⅓ the luminance of the high luminance display.

The current supply capability represents a magnitude of the current flowing between the source and drain with respect to the gate voltage. If the gate voltage is the same, more current flows through a transistor that is higher in the current supply capability than a transistor that is lower in the current supply capability.

The current supply capability of the transistor varies depending on a composition and crystal quality of a semiconductor doped into a channel portion. The channel portion is a region where a semiconductor layer and a gate electrode overlap. In a case that the compositions and crystal qualities of the semiconductors are the same, a size of the channel portion can be varied to differentiate the current supply capability. For example, a channel length of the channel portion of the first drive transistor Ta which preferably has high current supply capability is to be shorter than that of the second drive transistor Tb which has preferably lower current supply capability. Alternatively, a channel width of the channel portion of the first drive transistor Ta which preferably has high current supply capability is to be larger than that of the second drive transistor Tb which has preferably lower current supply capability.

Furthermore, in the pixel circuit SP having the above-described configuration, the number of gray scales used is not reduced, so the gray scale expression is not be impaired even in the case of the low luminance display. Furthermore, the further lower luminance display can be realized by using the light emission control transistor Te in combination with the configuration for adjusting the period for supplying the current to the light-emitting element ES at the time of low luminance display.

The switching of the switching control signal en may be configured to be performed based on an output of a sensor for measuring the luminance of an external light that is provided to the display device. In other words, in a case that the luminance of the external light is greater than a first threshold value, the switching control signal en is switched from Low to Hight. Conversely, in a case that the luminance of the external light is lower than a second threshold value, the switching control signal en is switched from Hight to Low. Note that here, by providing a range between the first threshold value and a 21th threshold value, frequent switching between the low luminance display and the high luminance display can be suppressed.

Furthermore, the switching of the switching control signal en may be configured to be performed in conjunction with a headlight or the like of a vehicle that is manually or automatically turned on and off in a case that the display device is mounted on the vehicle. In other words, the low luminance display is carried out when the headlights are turned on, and the high luminance display is carried out when the headlights are turned off.

### Embodiment 2

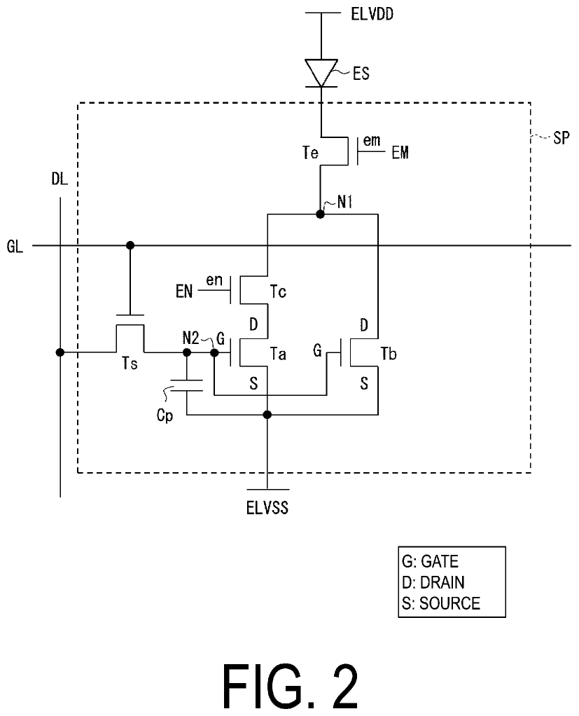

FIG. 2 is a circuit diagram illustrating a configuration example of a subpixel in a display region in a display device according to Embodiment 2. As illustrated in FIG. 2, in the display device according to Embodiment 2, the light-emitting element ES has the terminal on the current input side connected to the first power source wiring line ELVDD, and the terminal on the current output side connected to the terminal of the light emission control transistor Te on the current input side. Here, all of the transistors used in the pixel circuit SP are N-type (N-channel). The terminal of each of the first drive transistor Ta and the second drive transistor Tb on the current input side is connected to the terminal of the light emission control transistor Te on the current output side at the first node N1.

In the pixel circuit SP having such a configuration, by disposing the light-emitting element ES on a drain (D) side of the N-type transistor, the current flowing in the pixel circuit SP can be controlled by a value of a voltage Vg at a gate (G) of each of the first drive transistor Ta and the second drive transistor Tb.

Specifically, the voltage Vg at each gate (G) of the first drive transistor Ta and the second drive transistor Tb is equal to a voltage Vd of the data signal line DL. As a result, the first drive transistor Ta and the second drive transistor Tb supply a constant current when driving in a saturation region, and stabilize without being affected by the deterioration of the light-emitting element ES. In other words, a configuration resistant to the deterioration of the light-emitting element ES can be provided.

### Embodiment 3

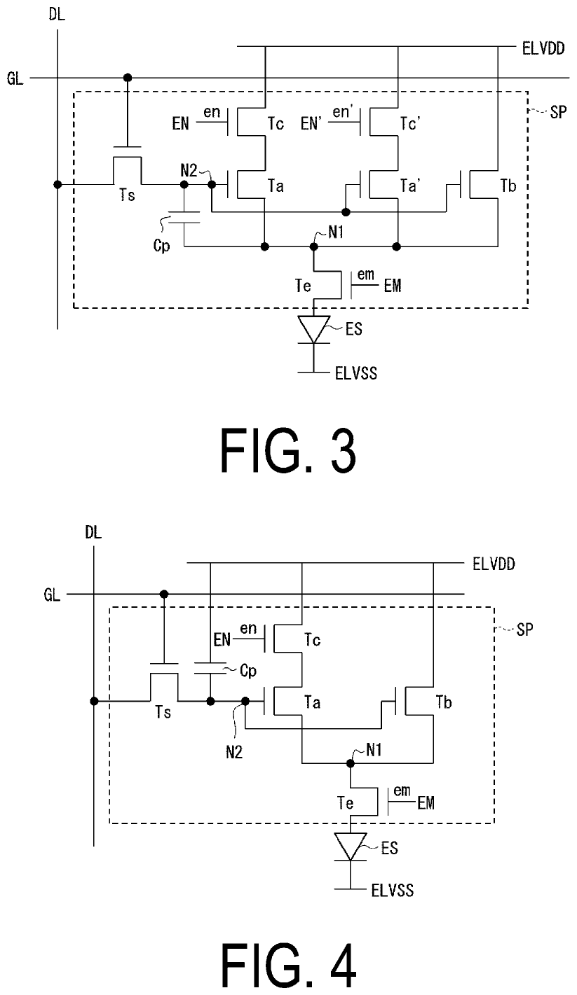

FIG. 3 is a circuit diagram illustrating a configuration example of a subpixel in a display region in a display device according to Embodiment 3. As illustrated in FIG. 3, in the display device according to Embodiment 3, in addition to the first drive transistor Ta and the second drive transistor Tb, a first drive transistor Ta′ as the third drive transistor is provided that drives the light-emitting elements ES.

Similar to the first drive transistor Ta, the first drive transistor Ta′ as the third transistor is also connected to a switching control transistor Tc′. A switching control signal line EN′ is connected to a control terminal of the switching control transistor Tc′, to which a switching control signal en′ is input.

In a pixel circuit SP having such a configuration, four-level luminance adjustment is possible. In other words, both the switching control signal en and the switching control signal en′ are set to Low. This can supply a current corresponding to the gray scale only from the second drive transistor Tb to the light-emitting element ES to realize the lowest luminance display.

Additionally, both the switching control signal en and the switching control signal en′ are set to Hight. This can supply a current corresponding to the gray scale from three of the second drive transistor Tb, the first drive transistor Ta, and the first drive transistor Ta′ to the light-emitting element ES to realize the highest luminance display.

Furthermore, the switching control signal en is set to Hight and the switching control signal en′ is set to Low. This can supply a current corresponding to the gray scale from two of the first drive transistor Ta and the second drive transistor Tb to the light-emitting element ES. In contrast to the above, the switching control signal en is set to Low, and the switching control signal en′ is set to Hight. This can supply a current corresponding to the gray scale from two of the first drive transistor Ta′ and the second drive transistor Tb to the light-emitting element ES.

In this case, the current supply capabilities of the first drive transistor Ta and the first drive transistor Ta′ are differentiated to enable the four-level luminance adjustment by switching the switching control signal en and the switching control signal en′. Note that four or more drive transistors may be used.

In the display device according to Embodiment 3, the luminance can be switched between three or more levels, and thus, intermediate luminance displays suitable for an early evening or a dim daytime such as a cloudy day and a rainy day can be provided between the high luminance display for a bright daytime and the low luminance display for a dark night-time.

### Embodiment 4

FIG. 4 is a circuit diagram illustrating a configuration example of a subpixel in a display region in a display device according to Embodiment 4. As illustrated in FIG. 4, in the display device according to Embodiment 4, a disposition position of the capacitances Cp is different from that in the pixel circuits SP of the display device according to Embodiment 4 illustrated in FIG. 1. In the display device according to Embodiment 4, the capacitance Cp is disposed between the second node N2 and the first power source wiring line ELVDD.

The capacitance Cp may be disposed in parallel with the switch transistor Ts, and basically, the capacitance Cp may be appropriately disposed according to the manner of internal security or external security.

### Embodiment 5

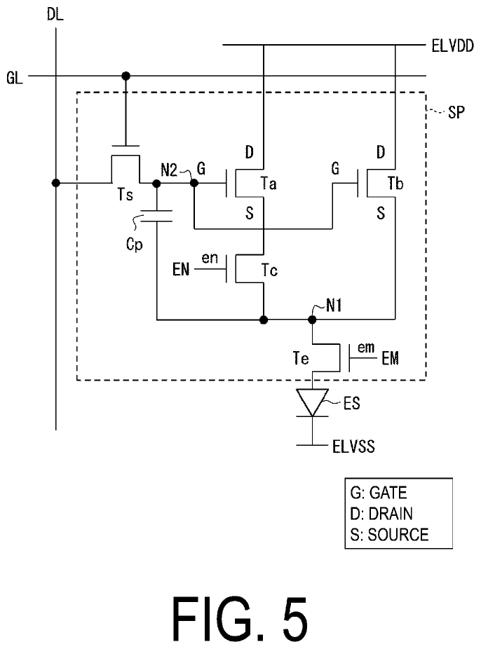

FIG. 5 is a circuit diagram illustrating a configuration example of a subpixel in a display region in a display device according to Embodiment 5. As illustrated in FIG. 5, in the display device according to Embodiment 5, the switching control transistor Tc is disposed on the current output side of the first drive transistor Ta. In other words, the terminal of the first drive transistor Ta on the current output side is connected to the terminal of the switching control transistor Tc on the current input side, and the terminal of the switching control transistor Tc on the current output side is connected via the light emission control transistor Te to the light-emitting element ES at the first node N1. Here, all of the transistors used in the pixel circuit SP are N-type.

In this manner, the switching control transistor Tc may be disposed between the first power source wiring line ELVDD and the first node N1, in series with respect to the first drive transistor Ta.

### Embodiment 6

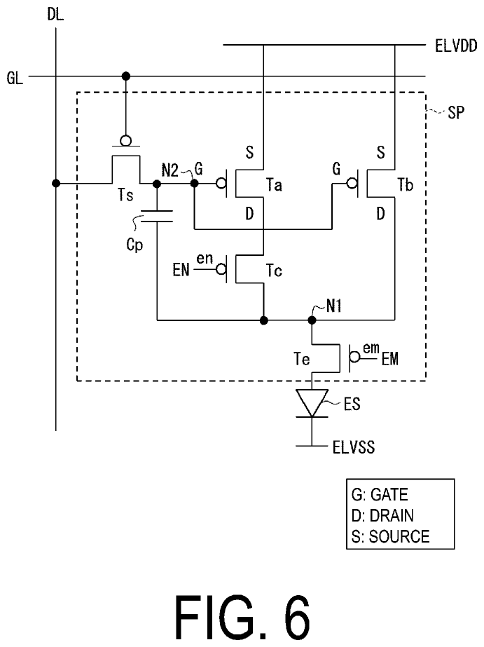

FIG. 6 is a circuit diagram illustrating a configuration example of a subpixel in a display region in a display device according to Embodiment 6. As illustrated in FIG. 6, in the display device according to Embodiment 6, similarly to the display device according to Embodiment 5, the switching control transistor Tc is disposed on the current output side of the first drive transistor Ta. A difference from the display device according to Embodiment 5 is in that all of the transistors used in the pixel circuit SP are P-type (P-channel).

As illustrated in FIG. 5, in the case that the first drive transistor Ta is constituted by an N-type transistor, the switching control transistor Tc is arranged on a source (S) side. In this case, drawing from a parasitic capacitance when the switching control transistor Tc is turned off or off causes a voltage Vs at the source (S) of the first drive transistor Ta to fluctuate, and the fluctuation, as noise, affects the current flowing through the first drive transistor Ta.

In contrast, as illustrated in FIG. 6, in a case that all of the transistors are P-type and the first drive transistor Ta is constituted by a P-type transistor, the switching control transistor Tc can be connected to the drain (D) side of the first drive transistor Ta. This can eliminate the fluctuation in the voltage Vg at the gate (G) of the first drive transistor Ta when the switching control transistor Tc is turned off or off to allow the light-emitting element ES to stably emit the light.

### Embodiment 7

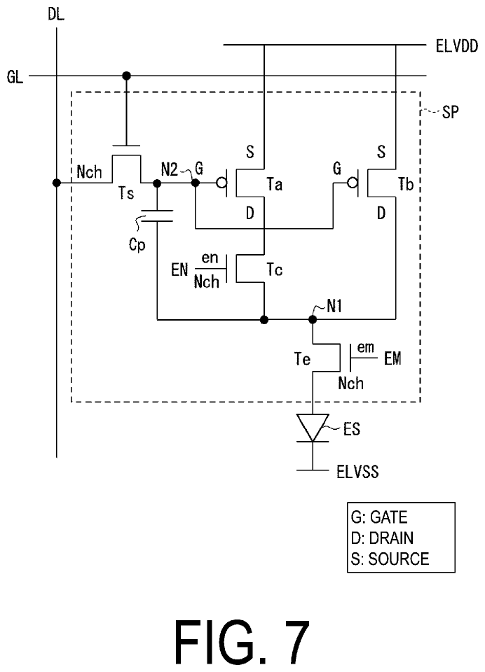

FIG. 7 is a circuit diagram illustrating a configuration example of a subpixel in a display region in a display device according to Embodiment 7. As illustrated in FIG. 7, in the display device according to Embodiment 7, the transistors used in the pixel circuit SP are P-type and N-type mixedly.

As illustrated in FIG. 7, in the display device according to Embodiment 7, a difference from the pixel circuit SP of the display device according to Embodiment 6 illustrated in FIG. 6 is in that three of the switching control transistor Tc, the light emission control transistor Te, and the switch transistor Ts are constituted by N-type transistors.

In a case that the N-type transistor is formed from an InGaZnO type oxide semiconductor, a leakage current can be suppressed low, so there is an effect that black floating caused by leakage current (light emission due to micro-current) can be suppressed compared to the display device according to Embodiment 6. The P-type transistor can be constituted by LTPS (low-temperature polysilicon), for example.

### Embodiment 8

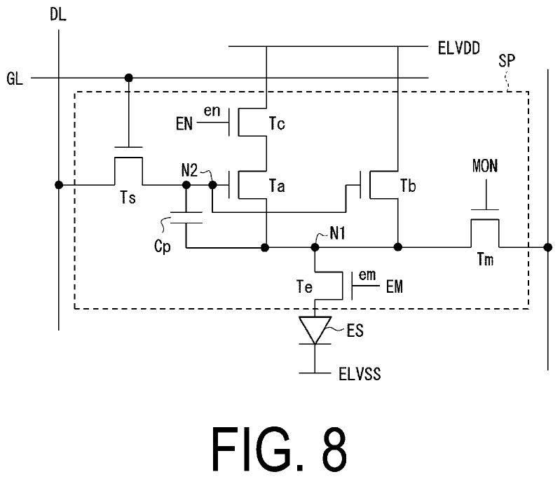

FIG. 8 is a circuit diagram illustrating a configuration example of a subpixel in a display region in a display device according to Embodiment 8. As illustrated in FIG. 8, in the display device according to Embodiment 8, a detection transistor Tm and a control signal line MON connected to a control terminal of the detection transistor Tm are added to the pixel circuit SP of the display device according to Embodiment 1 illustrated in FIG. 1. The detection transistor Tm has one terminal connected to the first node N1 and the other terminal connected to an external compensation circuit (not illustrated).

In such a pixel circuit SP, the detection transistor Tm detects currents flowing through the first drive transistor Ta and the second drive transistor Tb, and a current flowing through the light-emitting element ES. Then, the external compensation circuit detects a degree and variation of the deterioration of the first drive transistor Ta, the second drive transistor Tb, and the light-emitting element ES based on the current detected by the detection transistor Tm, and feeds back these into the video signal. Consequently, the uniform luminance expression with no luminance unevenness can be realized.

In also reading the currents flowing through the first drive transistor Ta and the second drive transistor Tb, the current flowing through only the second drive transistor Tb and the total value of the currents flowing through the second drive transistor Tb and the first drive transistor Ta can be detected by turning on and off the switching control transistor Tc. By subtracting the current value flowing through only the second drive transistor Tb from the total value of the currents flowing through the second drive transistor Tb and the first drive transistor Ta, the current value flowing through the first drive transistor Ta can be determined. Accordingly, each of the first drive transistor Ta and the second drive transistor Tb can be compensated for.

### Embodiment 9

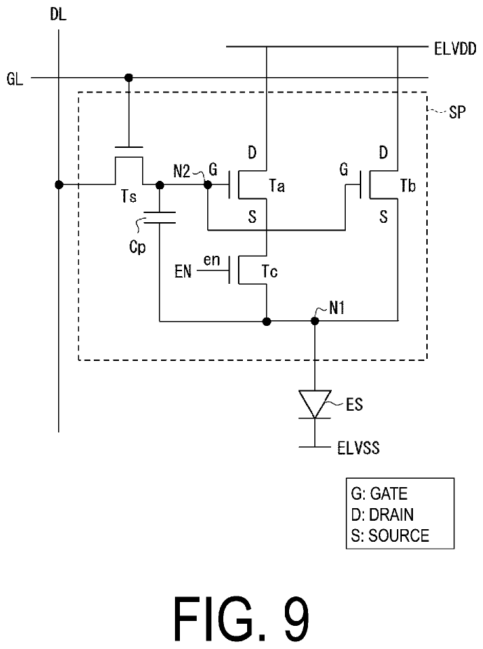

FIG. 9 is a circuit diagram illustrating a configuration example of a subpixel in a display region in a display device according to Embodiment 9. As illustrated in FIG. 9, in the display device according to Embodiment 9, the light emission control transistor Te is omitted in the pixel circuits SP of the display device according to Embodiment 1 illustrated in FIG. 1. The terminal of the light-emitting element ES on the current output side is connected to the first node N1.

In a case that the overall luminance adjustment is fixed to two levels that is switched due to switching off and off of the switching control transistor Tc, the light emission control transistor Te can be omitted. In a case that the light emission control transistor Te is omitted, the light emission control signal line EM and the emission driver for controlling the light emission control signal em flowing through the light emission control signal line EM can be deleted, which can give a configuration advantageous for frame narrowing of the display device.

Note that in Embodiments 1 to 9 described above, the second drive transistor Tb on the current input side is configured to be connected to the first power source wiring line ELVDD such that a current is always supplied. However, the second drive transistor Tb may also be configured, similar to the first drive transistor Ta, to be connected to the light emission control transistor that turns on and off the supply of current from the second drive transistor Tb.

### Supplement

An electro-optical element (an electro-optical element whose luminance and transmittance are controlled by an electric current) that is provided in a display device according to the present embodiment is not particularly limited thereto. Examples of the display device according to the present embodiment include an organic Electro Luminescence (EL) display provided with the Organic Light Emitting Diode (OLED) as the electro-optical element, an inorganic EL display provided with an inorganic light emitting diode as the electro-optical element, and a Quantum dot Light Emitting Diode (QLED) display provided with a QLED as the electro-optical element.

A display device according to Aspect 1 of the present invention includes pixel circuits (SP) arranged in a matrix shape, a first power source wiring line ELVDD provided with a first power supply voltage, a second power source wiring line ELVSS provided with a second power supply voltage, and data signal lines DL each provided for each of columns and provided with a data voltage, wherein the pixel circuit includes a light-emitting element ES disposed between the first power source wiring line and the second power source wiring line and driven by a current, first and second conductive terminals of a first drive transistor Ta and first and second conductive terminals of a switching control transistor Tc which are disposed between the first power source wiring line and the second power source wiring line, and connected in series with the light-emitting element, and first and second conductive terminals of a second drive transistor Tb which are disposed between the first power source wiring line and the second power source wiring line, connected in series with the light-emitting element, and connected in parallel with the first and second conductive terminals of the first drive transistor and the first and second conductive terminals of the switching control transistor which are connected in series, and a control terminal of the first drive transistor is electrically connected to a control terminal of the second drive transistor to be applied with a common signal.

In the display device according to Aspect 2 of the present invention in Aspect 1, the pixel circuit may further include a writing control transistor, and the control terminals of the first and second drive transistors may be connected via the writing control transistor to one data signal line of the data signal lines each provided for each of columns.

In the display device according to Aspect 3 of the present invention in Aspect 1 or 2, current supply capabilities of the first drive transistor and the second drive transistor may be different.

In the display device according to Aspect 4 of the present invention in Aspect 1, 2, or 3, the current supply capability of the first drive transistor may be higher than that of the second drive transistor.

In the display device according to Aspect 5 of the present invention in Aspect 1, 2, 3, or 4, sizes of channel portions of the first drive transistor and the second drive transistor may be different.

In the display device according to Aspect 6 of the present invention in Aspect 5, a channel length of the channel portion of the first drive transistor may be shorter than that of the second drive transistor.

In the display device according to Aspect 7 of the present invention in Aspect 5, a channel width of the channel portion of the first drive transistor may be larger than that of the second drive transistor.

In the display device according to Aspect 8 of the present invention in Aspect 1, 2, 3, 4, 5, 6, or 7, the pixel circuit may further include a light emission control transistor provided between the first power source wiring line and the second power source wiring line, the light emission control transistor being provided in series with the light-emitting element to control an on state and an off state of a current flowing through the light-emitting element.

In the display device according to Aspect 9 of the present invention in Aspect 10, a control terminal of the switching control transistor may be connected to a switching control signal line, and a control terminal of the light emission control transistor may be connected to a light emission control signal line.

In the display device according to Aspect 10 of the present invention in Aspect 9, a plurality of the switching control signal lines may be formed, and a common signal may be input to each of the plurality of the switching control signal lines, and a plurality of the light emission control signal lines may be formed, and different signals may be input into the plurality of the light emission control signal lines.

In the display device according to Aspect 11 of the present invention in any one of Aspects 1 to 10, the pixel circuit may further include a capacitance element, a first conductive terminal of the capacitance element may be connected to the control terminals of the first and second drive transistors, and a second conductive terminal of the capacitance element may be connected to one of the conductive terminals of the first drive transistor and is connected to one of the conductive terminals of the second drive transistor.

In the display device according to Aspect 12 of the present invention in any one of Aspects 1 to 10, the pixel circuit may further include a capacitance element, and the capacitance element may be connected between the control terminals of the first and second drive transistors, and the first power source wiring line.

In the display device according to Aspect 13 of the present invention in any one of Aspects 1 to 10, the pixel circuit may further include a capacitance element, and the capacitance element may be connected between the control terminals of the first and second drive transistors, and the second power source wiring line.

In a driving method for a display device according to Aspect 14 of the present invention, the display device being according to any one of Aspects 1 to 12, the display device includes a first luminance mode and a second luminance mode with a luminance lower than the first luminance mode, the switching control transistor is in an off state in the second luminance mode, and the switching control transistor is in an on state in the first luminance mode.

In the display method for the display device according to Aspect 15 of the present invention in Aspect 14, the on and off states of the switching control transistor may be switched to switch between the first luminance mode and the second luminance mode.

In the display method for the display device according to Aspect 16 of the present invention in Aspect 14 or 15, a threshold value switching between the first luminance mode and the second luminance mode may be included, and in a case that an external light is greater than the threshold value, the switching control transistor may be set to the on state, and in a case that the external light is equal to or less than the threshold value, the switching control transistor may be set to the off state.

The present invention is not limited to each of the embodiments described above, and various modifications may be made within the scope of the claims. Embodiments obtained by appropriately combining technical approaches disclosed in each of the different embodiments also fall within the technical scope of the present invention. Moreover, novel technical features can be formed by combining the technical approaches disclosed in the embodiments.

### REFERENCE SIGNS LIST

CP Capacitance
Ta First drive transistor
Tb Second drive transistor
Tc Switching control transistor
Te Light emission control transistor
Tm Detection transistor
Ts Switch transistor (writing control transistor)
ES Light-emitting element
ELVDD First power source wiring line
ELVSS Second power source wiring line

1. A display device comprising:
pixel circuits arranged in a matrix shape;
a first power source wiring line provided with a first power supply voltage;
a second power source wiring line provided with a second power supply voltage; and
data signal lines each provided for each of columns and provided with a data voltage,
wherein the pixel circuit includes
a light-emitting element disposed between the first power source wiring line and the second power source wiring line and driven by a current,
first and second conductive terminals of a first drive transistor and first and second conductive terminals of a switching control transistor which are disposed between the first power source wiring line and the second power source wiring line, and connected in series with the light-emitting element, and
first and second conductive terminals of a second drive transistor which are disposed between the first power source wiring line and the second power source wiring line, connected in series with the light-emitting element, and connected in parallel with the first and second conductive terminals of the first drive transistor and the first and second conductive terminals of the switching control transistor which are connected in series, and
a control terminal of the first drive transistor is electrically connected to a control terminal of the second drive transistor to be applied with a common signal.

2. The display device according to claim 1,
wherein the pixel circuit further includes a writing control transistor, and
the control terminals of the first and second drive transistors are connected via the writing control transistor to one data signal line of the data signal lines each provided for each of columns.

3. The display device according to claim 1,
wherein current supply capabilities of the first drive transistor and the second drive transistor are different.

4. The display device according to claim 1,
wherein the current supply capability of the first drive transistor is higher than that of the second drive transistor.

5. The display device according to claim 1,
wherein sizes of channel portions of the first drive transistor and the second drive transistor are different.

6. The display device according to claim 5,
wherein a channel length of a channel portion of the first drive transistor is shorter than that of the second drive transistor.

7. The display device according to claim 5,
wherein a channel width of a channel portion of the first drive transistor is larger than that of the second drive transistor.

8. The display device according to claim 1,
wherein the pixel circuit further includes a light emission control transistor provided between the first power source wiring line and the second power source wiring line, the light emission control transistor being provided in series with the light-emitting element to control an on state and an off state of a current flowing through the light-emitting element.

9. The display device according to claim 8,
wherein a control terminal of the switching control transistor is connected to a switching control signal line, and
a control terminal of the light emission control transistor is connected to a light emission control signal line.

10. The display device according to claim 9,
wherein the switching control signal line includes a plurality of first signal lines, and a common signal is input to each of the plurality of the first signal lines, and
the light emission control signal lines includes a plurality of second signal lines, and different signals are input into the plurality of the second signal lines.

11. The display device according to claim 1,
wherein the pixel circuit further includes a capacitance element,
a first conductive terminal of the capacitance element is connected to the control terminals of the first and second drive transistors, and
a second conductive terminal of the capacitance element is connected to one of the conductive terminals of the first drive transistor and is connected to one of the conductive terminals of the second drive transistor.

12. The display device according to claim 1,
wherein the pixel circuit further includes a capacitance element, and
the capacitance element is connected between the control terminals of the first and second drive transistors, and the first power source wiring line.

13. The display device according to claim 1,
wherein the pixel circuit further includes a capacitance element, and
the capacitance element is connected between the control terminals of the first and second drive transistors, and the second power source wiring line.

14. A driving method for a display device recited in claim 1,
wherein the display device includes a first luminance mode and a second luminance mode with a luminance lower than the first luminance mode,
the switching control transistor is in an off state in the second luminance mode, and
the switching control transistor is in an on state in the first luminance mode.

15. The driving method according to claim 14,
wherein the on and off states of the switching control transistor are switched to switch between the first luminance mode and the second luminance mode.

16. The driving method according to claim 14,
wherein a threshold value switching between the first luminance mode and the second luminance mode is included, and
in a case that an external light is greater than the threshold value, the switching control transistor is set to the on state, and in a case that the external light is equal to or less than the threshold value, the switching control transistor is set to the off state.
